(19) United States
(12) Patent Application Publication
(10) Pub. No.: US 2020/0132734 A1
(43) Pub. Date: Apr. 30, 2020

(54) DETECTION CIRCUIT AND DETECTION METHOD FOR ON-THE-GO DEVICE, AND TERMINAL

(71) Applicant: HUAWEI TECHNOLOGIES CO., LTD., Shenzhen (CN)

(72) Inventors: Liang ZHANG, Xi'an (CN); Chao WANG, Xi'an (CN); Bo XU, Xi'an (CN)

(21) Appl. No.: 16/463,380

(22) PCT Filed: Feb. 27, 2017
(86) PCT No.: PCT/CN2017/074988

§ 371 Date: May 23, 2019

(30) Foreign Application Priority Data
Nov. 23, 2016 (CN) 201611038369.7

(51) Int. Cl. G01R 19/165; G06F 13/42; G01R 15/04; G06F 1/26; G06F 1/28

(52) U.S. Cl. CPC G01R 19/16528; G06F 13/4295; G06F 1/28; G06F 1/266; G01R 15/04

(57) ABSTRACT

A detection circuit and a detection method for an on-the-go device, and a terminal are disclosed. The detection circuit includes a detection unit, a detection end, and a detection chip. The detection unit includes a voltage source and a first resistor that are connected in series, the voltage source is configured to generate a first voltage, and the first resistor is configured to divide the first voltage, to obtain a second voltage. The detection end is connected to an external device and the detection unit, and is configured to provide a connection interface between the detection circuit and the external device. The detection chip is connected to the first resistor, and is configured to determine, when the second voltage is less than a specified voltage, that the external device is an OTG device.

This application claims priority to Chinese Patent No. 201611038369.7 filed with the Chinese Patent Office on Nov. 23, 2016 and entitled “ON-THE-GO OTG IDENTIFICATION METHOD AND DEVICE”, which is incorporated herein by reference in its entirety. For mere brief description, the original text is not repeated herein in its entirety.

### TECHNICAL FIELD

This application relates to the field of circuit technologies, and in particular, to a detection circuit and a detection method for an on-the-go device, and a terminal.

### BACKGROUND

In recent years, on-the-go (On-The-Go, OTG) devices are more widely applied. Two OTG devices may directly transmit data to each other without a personal computer (Personal Computer, PC). Therefore, data exchange between devices is simpler and faster. An OTG device may be a PC, a mobile phone, a removable hard disk, a printer, a USB flash drive, or the like. In two OTG devices exchanging data, one OTG device functions as a host and is configured to control a data sending and receiving process between the two OTG devices, and the other OTG device is configured to cooperate with the OTG device functioning as the host in executing sending and receiving instructions.

The OTG device functioning as the host is usually a device having a universal serial bus (Universal Serial Bus, USB) host controller, such as a PC, a mobile phone, a removable hard disk, or a printer. When an external device is connected to the OTG device functioning as the host, the host needs to detect whether the external device is an OTG device. A solution of detecting whether an external device is an OTG device may be shown in FIG. 1. In FIG. 1, a detection chip is a chip that is in the host and that is configured to: detect whether an external device is an OTG device and control the data sending and receiving process between the two OTG devices. A specified pin in the detection chip is a pin configured to detect whether an external device is an OTG device. A detection end is an interface that is in the host and that is configured to connect to the external device. A current source inside the detection chip generates a current, and inputs the current into the detection end through the specified pin. Then the detection chip detects a voltage at the specified pin by using a comparator integrated in the detection chip. When the voltage at the specified pin is less than a preset voltage threshold, that is, resistance of the external device is less than a preset resistance threshold, it is determined that the external device is an OTG device. For example, when the detection chip in the host is PMI8952, the specified pin is a USB_PHY_ID pin, and the detection end is a USB_ID interface, a structure of a detection circuit may be shown in FIG. 2, where R is equivalent resistance of the external device. In FIG. 2, the PMI8952 inputs a current of 51 uA into the USB_ID interface through the USB_PHY_ID pin, then detects a voltage of the USB_PHY_ID pin by using a comparator integrated in the PMI8952. When the voltage of the USB_PHY_ID pin is greater than 1 V, that is, R is less than 19 kΩ (1 V/51 uA≈19 kΩ), the PMI8952 determines that the external device is an OTG device.

The foregoing method for detecting whether an external device is an OTG device has the following problem: There are a plurality of current sources inside the detection chip (for example, the PMI8952 shown in FIG. 2), and when the detection chip is used for different purposes, currents with different magnitudes may be generated. A polling switching manner is used for the plurality of current sources inside the detection chip, so that the detection chip outputs currents with different magnitudes in a polling manner. Therefore, when the detection chip is used to detect whether the external device is an OTG device, a current value of the current input by the detection chip into the USB_ID interface through the USB_PHY_ID pin may be inaccurate because of polling switching of the current sources, and further, accuracy of a detection result of the detection circuit is affected.

In conclusion, in the prior art, the solution of detecting whether an external device is an OTG device has a problem of an inaccurate detection result.

### SUMMARY

Embodiments of this application provide a detection circuit and a detection method for an on-the-go device, and a terminal, to resolve a problem of an inaccurate detection result in an existing OTG device detection solution.

According to a first aspect, this application provides a detection circuit for an OTG device, and the detection circuit includes a detection unit, a detection end, and a detection chip, where a voltage source included in the detection unit is configured to generate a first voltage, a first resistor included in the detection unit is configured to divide first voltage, to obtain a second voltage; the detection end is connected to an external device and the detection unit, and is configured to provide a connection interface between the detection circuit and the external device; and the detection chip is connected to the first resistor, and is configured to determine, when the second voltage is less than a specified voltage, that the external device is an OTG device.

In addition, the detection chip may be further configured to determine, when the second voltage is greater than or equal to the specified voltage, that the external device connected to the detection end is not an OTG device.

Better power supply quality of the voltage source generating the first voltage, that is, a more stable voltage value of the first voltage output by the voltage source, indicates a more accurate detection result.

In the detection circuit provided in the first aspect, the first resistor included in the detection unit divides the first voltage generated by the voltage source, to obtain the second voltage, and the detection chip determines, when the second voltage is less than the specified voltage, that the external device is an OTG device. Compared with a prior-art solution in which a detection chip outputs a current to detect whether an external device is an OTG device, when the detection circuit provided in the first aspect is used to detect whether an external device is an OTG device, because the first voltage generated by the voltage source is relatively stable, a detection result obtained after the detection chip determines, based on the second voltage obtained after the first resistor divides the first voltage, whether the external device is an OTG device is more accurate. Therefore, the detection result obtained after the detection circuit provided in the first aspect is used to detect whether the external device is an OTG device is more accurate.

In a possible design, the detection chip may be further configured to output a specified current, and the output specified current is less than a current flowing through the first resistor.

In the foregoing solution, the specified current is less than the current flowing through the first resistor. Therefore, a case of an inaccurate detection result caused by outputting the specified current in a polling switching manner by the detection chip can be avoided. A larger difference between the current flowing through the first resistor and the specified current indicates smaller impact of the specified current on the detection result and a more accurate detection result of the detection circuit.

In the foregoing solution, a value of the first voltage, the first resistor, or the specified current may be set to change a detection threshold of the detection circuit, and when a resistance value of the external device is less than the detection threshold, the detection chip determines that the external device is an OTG device.

In a possible design, the detection unit may further include a second resistor, the second resistor is connected to the first resistor and the detection chip, and the second resistor is configured to divide the second voltage.

Adding the second resistor to the detection unit reduces a magnitude of a current flowing from the voltage source to the external device, thereby avoiding an excessive leakage current in the OTG device in which the detection circuit is located when the external device is connected to the OTG device, and preventing power from being consumed too fast. In addition, in the detection circuit, a resistance value of the second resistor may be further adjusted to change the detection threshold of the detection circuit, thereby effectively avoiding misidentification caused due to a stain on the interface of the detection end, and reducing a field failure rate (Field Failure Rate, FFR) of the OTG device in which the detection circuit is located.

According to a second aspect, this application provides a terminal, where the terminal includes the detection circuit according to the first aspect or any possible design of the first aspect.

In the terminal provided in the second aspect, the first resistor included in the detection unit divides the first voltage generated by the voltage source, to obtain the second voltage, and the detection chip determines, when the second voltage is less than the specified voltage, that the external device is an OTG device. Compared with a prior-art solution in which a detection chip outputs a current to detect whether an external device is an OTG device, when the terminal provided in the second aspect is used to detect whether an external device is an OTG device, because the first voltage generated by the voltage source is relatively stable, a detection result obtained after the detection chip determines, based on the second voltage obtained after the first resistor divides the first voltage, whether the external device is an OTG device is more accurate. Therefore, the detection result obtained after the terminal provided in the second aspect is used to detect whether the external device is an OTG device is more accurate.

According to a third aspect, this application provides a detection method for an OTG device, where the method includes the following steps: generating, by a voltage source included in a detection unit in a detection circuit, a first voltage, and dividing, by a first resistor included in the detection unit, the first voltage, to obtain a second voltage; providing, by a detection end in the detection circuit, a connection interface between the detection circuit and an external device; and determining, by a detection chip in the detection circuit when the second voltage is less than a specified voltage, that the external device is an OTG device.

In addition, the detection chip may be further configured to determine, when the second voltage is greater than or equal to the specified voltage, that the external device is not an OTG device.

In the detection method for an OTG device provided in the third aspect, the first resistor included in the detection unit in the detection circuit divides the first voltage generated by the voltage source, to obtain the second voltage, and the detection chip in the detection circuit determines, when the second voltage is less than the specified voltage, that the external device is an OTG device. Compared with a prior-art solution in which a detection chip outputs a current to detect whether an external device is an OTG device, when the detection method provided in the third aspect is used to detect whether an external device connected to the detection circuit is an OTG device, because the first voltage generated by the voltage source is relatively stable, a detection result obtained after the detection chip determines, based on the second voltage obtained after the first resistor divides the first voltage, whether the external device is an OTG device is more accurate. Therefore, the detection result obtained after the detection method provided in the third aspect is used to detect whether the external device is an OTG device is more accurate.

In a possible design, the detection chip may be further configured to output a specified current to the detection unit, where the output specified current needs to be less than a current flowing through the first resistor.

In the foregoing solution, the specified current is less than the current flowing through the first resistor. Therefore, a case of an inaccurate detection result caused by outputting the specified current in a polling switching manner by the detection chip can be avoided. A larger difference between the current flowing through the first resistor and the specified current indicates smaller impact of the specified current on the detection result and a more accurate detection result of the detection circuit.

In the foregoing solution, a value of the first voltage, the first resistor, or the specified current may be set to change a detection threshold of the detection circuit, and when a resistance value of the external device is less than the detection threshold, the detection chip determines that the external device is an OTG device.

In a possible design, a second resistor included in the detection unit may divide the second voltage.

The second resistor in the detection unit divides the second voltage, so that a magnitude of a current flowing from the voltage source to the external device is reduced, thereby avoiding an excessive leakage current in the OTG device in which the detection circuit is located when the external device is connected to the OTG device, and preventing power from being consumed too fast. In addition, in the detection circuit, a resistance value of the second resistor may be further adjusted to change the detection threshold of the detection circuit, thereby effectively avoiding misidentification caused due to a stain on the interface of the detection end, and reducing an FFR of the OTG device in which the detection circuit is located.

### BRIEF DESCRIPTION OF DRAWINGS

FIG. 1 is a schematic diagram of a solution of detecting whether an external device is an OTG device according to the prior art;

FIG. 2 is a schematic circuit diagram of a solution of detecting whether an external device is an OTG device according to the prior art;

FIG. 3 is a schematic structural diagram of a detection circuit for an OTG device according to an embodiment of this application;

FIG. 4 is a schematic structural diagram of another detection circuit for an OTG device according to an embodiment of this application; and

FIG. 5 is a schematic flowchart of a detection method for an OTG device according to an embodiment of this application.

### DESCRIPTION OF EMBODIMENTS

The following further describes in detail the embodiments of this application with reference to accompanying drawings.

This application relates to detecting, by using a detection circuit for an OTG device, whether an external device connected to the detection circuit is an OTG device. The detection circuit may be disposed in an OTG device functioning as a host. The OTG device functioning as the host may use the detection circuit to detect whether an external device connected to the OTG device functioning as the host is an OTG device.

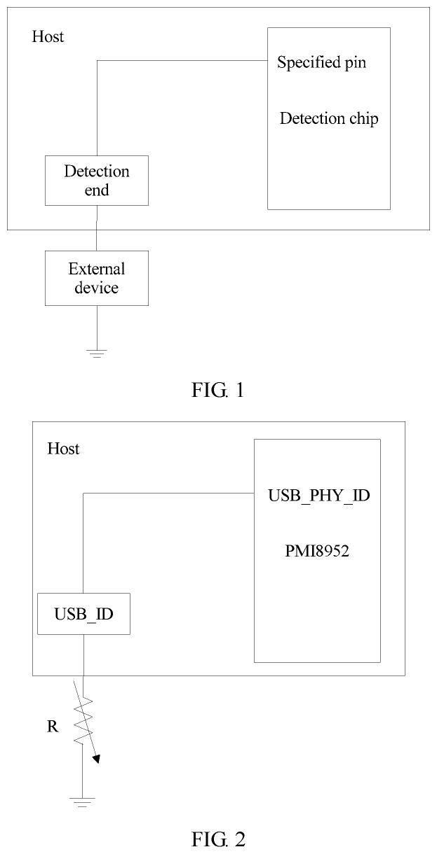

When the OTG device functioning as the host detects whether an external device connected to the OTG device functioning as the host is an OTG device, a solution shown in FIG. 1 is usually used. In the solution shown in FIG. 1, when a detection chip is used for different purposes, currents with different magnitudes may be generated, and the currents with the different magnitudes are output in a polling switching manner. For example, the detection chip is PMI8952. The PMI8952 may generate currents with four different magnitudes: 6 uA, 11 uA, 20 uA, and 51 uA. The currents with the four different magnitudes are output in the polling switching manner in an order of 6 uA→11 uA→20 uA→51 uA. When the PMI8952 detects whether an external device connected to the PMI8952 is an OTG device, the PMI8952 outputs a current of 51 uA to a USB_ID interface through a USB_PHY_ID pin. Then the PMI8952 detects a voltage at the USB_PHY_ID pin by using a comparator integrated in the PMI8952. When the voltage at the USB_PHY_ID pin is less than 1 V, that is, a resistance value of the external device is less than 19 kΩ (1 V/51 uA≈19 kΩ), it is determined that the external device connected to the USB_ID interface is an OTG device.

In the solution in the prior art, the currents with the four different magnitudes, namely, 6 uA, 11 uA, 20 uA, and 51 uA, are output in the polling switching manner. Therefore, when the PMI8952 outputs the current of 51 uA to the USB_ID interface through the USB_PHY_ID pin, a current value of the output current is probably not 51 uA, but an intermediate value of the currents with the four different magnitudes output in the polling switching process. Consequently, when it is detected, based on the current, whether the external device connected to the USB_ID interface is an OTG device, there is a problem of an inaccurate detection result.

The embodiments of this application provide a detection circuit and a detection method for an OTG device, and a terminal, to resolve the problem of an inaccurate detection result in the existing OTG device detection solution. The detection method and the detection circuit are based on a same inventive concept. Because the detection method and the detection circuit use similar principles to resolve problems, reference may be mutually made between implementations of the detection circuit and the detection method. No repetition is provided.

It should be understood that in descriptions of this application, terms such as “first” and “second” are used only to distinguish purposes of the descriptions, and should not be construed as indicating or implying relative importance, nor as indicating or implying an order.

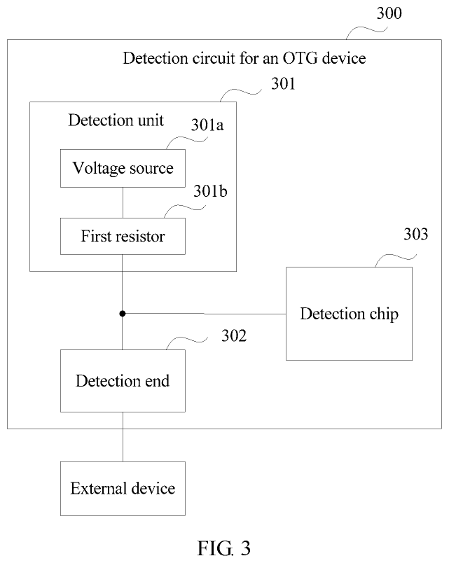

This application provides a detection circuit for an OTG device. Referring to FIG. 3, the detection circuit 300 for an OTG device (which is referred to as “detection circuit 300” for short below) includes a detection unit 301, a detection end 302, and a detection chip 303.

The detection unit 301 includes a voltage source 301a and a first resistor 301b that are connected in series. The voltage source 301a is configured to generate a first voltage. The first resistor 301b is configured to divide the first voltage, to obtain a second voltage. The detection end 302 is connected to an external device and the detection unit 301. The detection end 302 is configured to provide a connection interface between the detection circuit 300 and the external device. The detection chip 303 is connected to the first resistor 301b, and is configured to determine, when the second voltage is less than a specified voltage, that the external device connected to the detection end is an OTG device.

It should be noted that, in this embodiment of this application, the voltage source 301a is a voltage source that is constructed outside the detection chip 303 and that can stably output the first voltage. “External” in the external device is described in terms of an OTG device in which the detection circuit 300 is located. For example, if the OTG device in which the detection circuit 300 is located is a mobile phone, the external device is a device connected to the mobile phone through a USB interface of the mobile phone.

In addition, the detection chip 303 may be further configured to determine, when the second voltage is greater than or equal to the specified voltage, that the external device connected to the detection end is not an OTG device.

In this embodiment of this application, better power supply quality of the voltage source 301a generating the first voltage, that is, a more stable voltage value of the first voltage output by the voltage source 301a, indicates a more accurate detection result. Therefore, the voltage source 301a may use a low dropout regulator (Low Dropout Regulator, LDO). As stability of a voltage output by the LDO is good, accuracy of a detection result can be increased.

In this embodiment of this application, the detection end 302 is configured to provide the connection interface between the detection circuit 300 and the external device. The detection end 302 may be a USB interface of the OTG device in which the detection circuit 300 is located.

In the detection circuit 300 shown in FIG. 3, the first resistor 301b included in the detection unit 301 divides the first voltage generated by the voltage source 301a, to obtain the second voltage, and the detection chip 303 determines, when the second voltage is less than the specified voltage, that the external device is an OTG device. Compared with a prior-art solution in which a detection chip outputs a current to detect whether an external device is an OTG device, when the detection circuit 300 provided in this application is used to detect whether an external device connected to the detection end 302 is an OTG device, because the first voltage generated by the voltage source 301a is relatively stable, a detection result obtained after the detection chip 303 determines, based on the second voltage obtained after the first resistor 301b divides the first voltage, whether the external device is an OTG device is more accurate. Therefore, the detection result obtained after the detection circuit 300 provided in this application is used to detect whether the external device is an OTG device is more accurate.

For example, when the first voltage is 1.8 V, the first resistor is 1 kΩ, the specified voltage is 1 V, and a second voltage obtained after the first resistor divides the 1.8-V first voltage is less than the specified voltage 1 V, the detection chip 303 determines that the external device connected to the detection end 302 is an OTG device. In other words, when resistance of the external device is less than a detection threshold Rt, and Rt=1 V/((1.8 V−1 V)/1 kΩ)=1.25 kΩ, the detection chip 303 determines that the external device connected to the detection end 302 is an OTG device.

In addition, when the detection circuit 300 provided in this application is used to detect whether an external device is an OTG device, because both the first voltage and the first resistor can be changed, during the detection of the external device, the detection threshold Rt of the detection circuit 300 can be controlled by setting the first voltage and/or the first resistor. For example, when the detection end 302 is a USB interface, a stain on the USB interface may cause USB_ID to be micro short-circuited (with a resistance value of approximately several kilohms to tens of kilohms). If the resistance value is less than the detection threshold Rt of the detection circuit 300, the detection circuit 300 may incorrectly identify the stain on the USB interface as connection of an OTG device, resulting in misidentification. In this case, the detection threshold Rt of the detection circuit 300 may be changed by changing the first voltage and/or the first resistor in the detection circuit 300, thereby avoiding the foregoing misidentification.

In this embodiment of this application, the detection chip 303 may further output a specified current, and the specified current is less than a current flowing through the first resistor 301b.

In the foregoing implementation of the detection circuit 300, the detection chip 303 outputs the specified current still in a polling switching manner. However, because the specified current is less than the current flowing through the first resistor 301b, a case of an inaccurate detection result caused by outputting the specified current in the polling switching manner by the detection chip 303 can be avoided. A larger difference between the current flowing through the first resistor 301b and the specified current indicates smaller impact of the specified current on the detection result and a more accurate detection result of the detection circuit 300.

In the foregoing implementation, a magnitude of the specified current may further affect the detection threshold Rt of the detection circuit 300. For example, when the first voltage is 1.8 V, the first resistor is 1 kΩ, the specified voltage is 1 V, and the specified current is 51 uA, a maximum current of the voltage source 301a is I=1.8 V/1 kΩ=1.8 mA>51 uA. Therefore, the specified current output by the detection chip 303 in the polling switching manner has little impact on the detection result. In this case, the detection threshold Rt of the detection circuit 300 is Rt=1 V/((1.8 V−1 V)/1 kΩ-51 uA)≈1.335 kΩ. Compared with a solution in which the detection chip 303 does not output the specified current, the detection threshold Rt of detection circuit 300 increases. Therefore, in the foregoing implementation, the detection threshold Rt of the detection circuit 300 can be changed by changing a magnitude of the first voltage, the first resistor, or the specified current.

Optionally, the detection unit 301 may further include a second resistor, and the second resistor is connected to the first resistor 301b and the detection chip 303, and is configured to divide the second voltage.

Adding the second resistor to the detection unit 301 reduces a magnitude of a current flowing from the voltage source 301a to the external device, thereby avoiding an excessive leakage current in the OTG device in which the detection circuit 300 is located when the external device is connected to the OTG device, and preventing power from being consumed too fast. In addition, in the detection circuit 300, a resistance value of the second resistor may be further adjusted to change the detection threshold Rt of the detection circuit 300, thereby effectively avoiding misidentification caused due to a stain on the interface of the detection end 302, and reducing an FFR of the OTG device in which the detection circuit 300 is located.

For example, when the first voltage is 1.8 V, the first resistor is 1 kΩ, the specified voltage is 1 V, and the second resistor is 820Ω, the detection threshold Rt of the detection circuit is Rt=1 V/((1.8 V−1 V)/1 kΩ-51 uA)-820Ω≈515Ω. As can be learned, compared with a solution in which the second resistor is not added to the detection unit 301, the detection threshold Rt of the detection circuit 300 is reduced from 1.335 kΩ to 515Ω.

In this embodiment of this application, during selection of resistance values of the first resistor and the second resistor, if both the resistance values of the first resistor and the second resistor are very small, when the external device is connected to the detection end 302, the voltage source 301a generates a relatively large leakage current, causing an increase in power consumption of the entire detection circuit; or if both the resistance values of the first resistor and the second resistor are very large, consequently, a current of the voltage source 301a is very small, or even less than the specified current output by the detection chip 303, and accuracy of the detection result is affected. During actual implementation, the first resistor and the second resistor may be selected empirically.

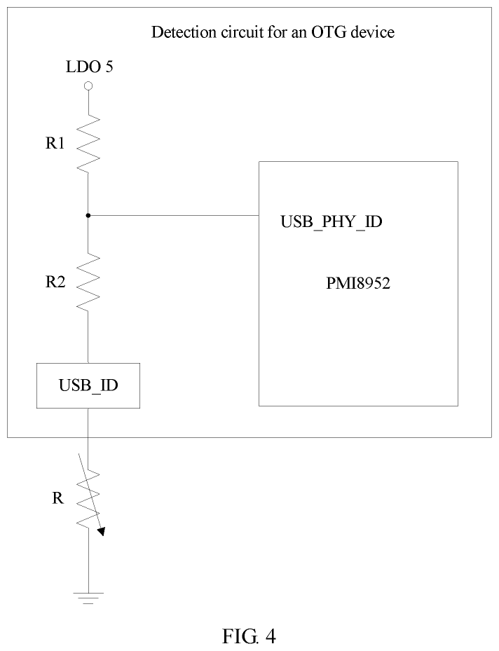

With reference to the foregoing descriptions of the detection circuit 300 for an OTG device and various possible implementations thereof, this application further provides a detection circuit for an OTG device shown in FIG. 4. The detection circuit may be considered as a specific implementation of the detection circuit 300 for an OTG device shown in FIG. 3.

In the detection circuit shown in FIG. 4, PMI8952 is a detection chip, an LDO 5 is a voltage source, R1 and R2 are respectively a first resistor and a second resistor, the PMI8952 is connected to R1 and R2 through a USB_PHY_ID pin, USB_ID is a detection end, and R is a resistance value of an external device. A first voltage generated by the voltage source LDO 5 is 1.8 V, R1=1.8 kΩ, and R2=820Ω. When the detection circuit for an OTG device shown in FIG. 4 is used to detect whether the external device connected to USB_ID is an OTG device, the PMI8952 outputs a specified current of 51 uA through the USB_PHY_ID pin in a polling switching manner. Because a maximum current I of the LDO 5 is I=1.8 V/(1 kΩ+820Ω)=0.98 mA>51 uA, the specified current output by the PMI8952 has little impact on a detection result.

A detection threshold Rt of the detection circuit for an OTG device shown in FIG. 4 is Rt=1 V/((1.8 V−1 V)/1 kΩ+51 uA)−820Ω=355Ω. Therefore, when the resistance value R of the external device is R<Rt, the PMI8952 determines that the external device connected to the USB_ID interface is an OTG device.

In conclusion, when the detection circuit for an OTG device provided in this application is used to detect whether an external device connected to the detection end is an OTG device, accuracy of a detection result can be increased, misidentification of the OTG device can be avoided, and an FFR of the OTG device in which the detection circuit is located is reduced.

Based on the foregoing embodiment, this application further provides a terminal. The terminal includes the detection circuit 300 shown in FIG. 3.

Specifically, the terminal may be a device such as a mobile phone, a personal computer (Personal Computer, PC), a personal tablet computer, a digital camera, or a printer.

The terminal may be configured to detect whether an external device connected to the terminal is an OTG device. For a specific implementation, refer to related descriptions of the detection circuit 300 shown in FIG. 3.

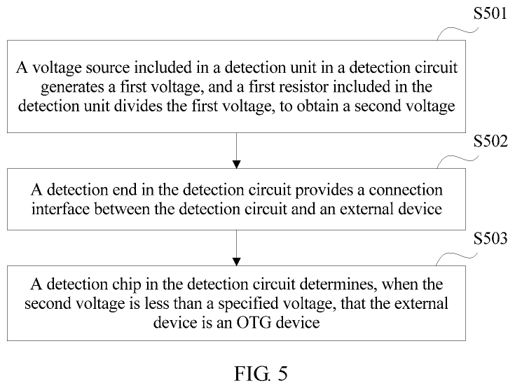

Based on the foregoing embodiment, this application further provides a detection method for an OTG device. An execution body of the detection method may be considered as the detection circuit 300 shown in FIG. 3. The detection circuit 300 may detect, by performing the method, whether an external device connected to the detection circuit 300 is an OTG device. As shown in FIG. 5, the method includes the following steps.

S501: The voltage source included in the detection unit in the detection circuit generates a first voltage, and the first resistor included in the detection unit divides the first voltage, to obtain a second voltage.

S502: The detection end in the detection circuit provides a connection interface between the detection circuit and an external device.

S503: The detection chip in the detection circuit determines, when the second voltage is less than a specified voltage, that the external device is an OTG device.

Optionally, the method further includes: outputting, by the detection chip, a specified current to the detection unit, where the specified current is less than a current flowing through the first resistor.

Optionally, the method further includes: dividing, by the second resistor included in the detection unit, the second voltage.

Optionally, the method further includes: determining, by the detection chip when the second voltage is greater than or equal to the specified voltage, that the external device is not an OTG device.

In the detection method for an OTG device shown in FIG. 5, the first resistor included in the detection unit in the detection circuit divides the first voltage generated by the voltage source, to obtain the second voltage, and the detection chip in the detection circuit determines, when the second voltage is less than the specified voltage, that the external device is an OTG device. Compared with a prior-art solution in which a detection chip outputs a current to detect whether an external device is an OTG device, when the detection method provided in this application is used to detect whether an external device connected to the detection circuit is an OTG device, because the first voltage generated by the voltage source is relatively stable, a detection result obtained after the detection chip determines, based on the second voltage obtained after the first resistor divides the first voltage, whether the external device is an OTG device is more accurate. Therefore, the detection result obtained after the detection method provided in this application is used to detect whether the external device is an OTG device is more accurate.

The method shown in FIG. 5 may be considered as a method used by the detection circuit 300 shown in FIG. 3 when the detection circuit 300 detects whether an external device connected to the detection circuit 300 is an OTG device. Therefore, for an implementation not explained and described in detail in the method shown in FIG. 5, refer to related descriptions of the detection circuit 300 shown in FIG. 3.

In conclusion, compared with a prior-art solution in which a detection chip outputs a current to detect whether an external device is an OTG device, when the detection circuit and the detection method for an OTG device, and the terminal that are provided in this application are used, because the first voltage generated by the voltage source is relatively stable, a detection result obtained after the detection chip determines, based on the second voltage obtained after the first resistor divides the first voltage, whether the external device is an OTG device is more accurate. Therefore, the detection result obtained after the detection circuit and the detection method for an OTG device, and the terminal that are provided in this application are used to detect whether the external device is an OTG device is more accurate.

A person skilled in the art should understand that the embodiments of this application may be provided as a method, a system, or a computer program product. Therefore, this application may use a form of hardware only embodiments, software only embodiments, or embodiments with a combination of software and hardware. Moreover, this application may use a form of a computer program product that is implemented on one or more computer-usable storage media (including but not limited to a disk memory, a CD-ROM, an optical memory, and the like) that include computer usable program code.

This application is described with reference to the flowcharts and/or block diagrams of the method, the device (system), and the computer program product according to the embodiments of this application. It should be understood that computer program instructions may be used to implement each process and/or each block in the flowcharts and/or the block diagrams and a combination of a process and/or a block in the flowcharts and/or the block diagrams. These computer program instructions may be provided for a general-purpose computer, a dedicated computer, an embedded processor, or a processor of any other programmable data processing device to generate a machine, so that the instructions executed by a computer or a processor of any other programmable data processing device generate an apparatus for implementing a specific function in one or more processes in the flowcharts and/or in one or more blocks in the block diagrams.

These computer program instructions may be stored in a computer readable memory that can instruct the computer or any other programmable data processing device to work in a specific manner, so that the instructions stored in the computer readable memory generate an artifact that includes an instruction apparatus. The instruction apparatus implements a specific function in one or more processes in the flowcharts and/or in one or more blocks in the block diagrams.

These computer program instructions may be loaded onto a computer or another programmable data processing device, so that a series of operations and steps are performed on the computer or the another programmable device, thereby generating computer-implemented processing. Therefore, the instructions executed on the computer or the another programmable device provide steps for implementing a specific function in one or more processes in the flowcharts and/or in one or more blocks in the block diagrams.

Obviously, a person skilled in the art can make various modifications and variations to the embodiments of this application without departing from the spirit and scope of the embodiments of this application. This application is intended to cover these modifications and variations provided that they fall within the scope of protection defined by the following claims and their equivalent technologies.

1. A detection circuit for an on-the-go (OTG) device, comprising:
a detection unit, wherein the detection unit comprises a voltage source and a first resistor that are connected in series, the voltage source is configured to generate a first voltage, and the first resistor is configured to divide the first voltage, to obtain a second voltage;
a detection end, connected to an external device and the detection unit, and configured to provide a connection interface between the detection circuit and the external device; and
a detection chip, connected to the first resistor, and configured to determine, when the second voltage is less than a specified voltage, that the external device is an OTG device.

2. The circuit according to claim 1, wherein the detection chip is further configured to output a specified current, and the specified current is less than a current flowing through the first resistor.

3. The circuit according to claim 1, wherein the detection unit further comprises a second resistor, the second resistor is connected to the first resistor and the detection chip, and the second resistor is configured to divide the second voltage.

4. The circuit according to claim 1, wherein the detection chip is further configured to determine, when the second voltage is greater than or equal to the specified voltage, that the external device is not an OTG device.

5. A terminal, comprising the detection circuit according to claim 1.

6. A detection method for an on-the-go (OTG) device, comprising:
generating, by a voltage source comprised in a detection unit in a detection circuit, a first voltage, and dividing, by a first resistor comprised in the detection unit, the first voltage, to obtain a second voltage;
providing, by a detection end in the detection circuit, a connection interface between the detection circuit and an external device; and
determining, by a detection chip in the detection circuit when the second voltage is less than a specified voltage, that the external device is an OTG device.

7. The method according to claim 6, further comprising:
outputting, by the detection chip, a specified current to the detection unit, wherein the specified current is less than a current flowing through the first resistor.

8. The method according to claim 6, further comprising:
dividing, by a second resistor comprised in the detection unit, the second voltage.

9. The method according to claim 6, further comprising:
determining, by the detection chip when the second voltage is greater than or equal to the specified voltage, that the external device is not an OTG device.

10. The circuit according to claim 2, wherein the detection unit further comprises a second resistor, the second resistor is connected to the first resistor and the detection chip, and the second resistor is configured to divide the second voltage.

11. The circuit according to claim 2, wherein the detection chip is further configured to determine, when the second voltage is greater than or equal to the specified voltage, that the external device is not an OTG device.

12. The circuit according to claim 3, wherein the detection chip is further configured to determine, when the second voltage is greater than or equal to the specified voltage, that the external device is not an OTG device.

13. The method according to claim 7, further comprising:
dividing, by a second resistor comprised in the detection unit, the second voltage.

14. The method according to claim 7, further comprising:
determining, by the detection chip when the second voltage is greater than or equal to the specified voltage, that the external device is not an OTG device.

15. The method according to claim 8, further comprising:
determining, by the detection chip when the second voltage is greater than or equal to the specified voltage, that the external device is not an OTG device.
